(19) United States
(12) Patent Application Publication
(10) Pub. No.: US 2024/0361507 A1
(43) Pub. Date: Oct. 31, 2024

(54) OPTICAL LAMINATE, POLARIZING PLATE, AND IMAGE DISPLAY DEVICE

(71) Applicant: FUJIFILM Corporation, Tokyo (JP)

(72) Inventors: Yuki NAKAMURA, Kanagawa (JP); Katsufumi OHMURO, Kanagawa (JP)

(73) Assignee: FUJIFILM Corporation, Tokyo (JP)

(21) Appl. No.: 18/770,376

(22) Filed: Jul. 11, 2024

Related U.S. Application Data
(63) Continuation of application No. PCT/JP2023/000056, filed on Jan. 5, 2023.

(30) Foreign Application Priority Data
Jan. 18, 2022 (JP) 2022-005657
Feb. 4, 2022 (JP) 2022-016237
Jul. 26, 2022 (JP) 2022-118953

(51) Int. Cl. G02B 5/30; C09J 7/38; G02F 1/1335; H10K 59/80

(52) U.S. Cl. CPC G02B 5/305; C09J 7/38; G02F 1/133528; H10K 59/8791; C09J 2203/318; C09J 2203/326; C09J 2301/302

(57) ABSTRACT

An optical laminate having a barrier layer having excellent adhesiveness to a pressure sensitive adhesive layer, a polarizing plate, and an image display device. The optical laminate has a film substrate, a barrier layer, and a pressure sensitive adhesive layer in this order, in which the barrier layer is formed of a composition for forming a barrier layer, containing a monomer having a polymerizable group, and satisfies Condition 1: a functional group that reacts with a hydroxyl group to form a covalent bond is present on a surface of the barrier layer on a pressure sensitive adhesive layer side and Condition 2: no hydroxyl group other than the hydroxyl group included in the functional group is present in a region from the surface of the barrier layer on the pressure sensitive adhesive layer side to a half of a thickness of the barrier layer.

### CROSS-REFERENCE TO RELATED APPLICATIONS

This application is a Continuation of PCT International Application No. PCT/JP2023/000056 filed on Jan. 5, 2023, which was published under PCT Article 21 (2) in Japanese, and which claims priority under 35 U.S.C. § 119 (a) to Japanese Patent Application No. 2022-005657 filed on Jan. 18, 2022, Japanese Patent Application No. 2022-016237 filed on Feb. 4, 2022, and Japanese Patent Application No. 2022-118953 filed on Jul. 26, 2022. The above applications are hereby expressly incorporated by reference, in their entirety, into the present application.

### BACKGROUND OF THE INVENTION

### 1. Field of the Invention

The present invention relates to an optical laminate, a polarizing plate, and an image display device.

### 2. Description of the Related Art

In-plane switching (IPS)-type and fringe field switching (FFS)-type liquid crystal display device systems are not in a mode in which an electric field is applied between upper and lower substrates and driven by the rise of liquid crystal molecules such as a twisted nematic (TN)-type or a vertical alignment (VA)-type, but are in a mode that is referred to as a horizontal electric field system in which liquid crystal molecules respond in a substrate in-plane direction due to the electric field including a component substantially parallel to a substrate surface.

In such a horizontal electric field system of a liquid crystal display device, a retardation layer using a cycloolefin-based polymer as a substrate is known to be used for the purpose of improving a change in display performance due to a change in temperature and humidity environment in a use environment.

For example, JP2014-032270A describes “a phase difference film having a protective film formed by cationic polymerization curing on both surfaces of an olefin-based resin film with an in-plane phase difference of 50 nm or more” ([Claim 1]).

### SUMMARY OF THE INVENTION

The present inventors have conducted studies on an optical laminate having a film substrate such as an olefin-based resin film, and a pressure sensitive adhesive layer. Thus, they have found that from the viewpoints of durability, suppression of a transfer of components of the pressure sensitive adhesive layer, and the like, there are some cases where a barrier layer is provided between the film substrate and the pressure sensitive adhesive layer, and depending on a type of the barrier layer, the adhesiveness to the pressure sensitive adhesive layer may be deteriorated.

Therefore, an object of the present invention is to provide an optical laminate having a barrier layer having excellent adhesiveness to a pressure sensitive adhesive layer, a polarizing plate, and an image display device.

The present inventors have conducted intensive studies to accomplish the object, and as a result, they have found that in an optical laminate having a film substrate, a barrier layer, and a pressure sensitive adhesive layer in this order, the adhesiveness to the pressure sensitive adhesive layer is improved by configuring the barrier layer to satisfy predetermined conditions, leading to completion of the present invention.

That is, the present inventors have found that the object can be accomplished by the following configurations.
[1] An optical laminate comprising, in the following order:
a film substrate;
a barrier layer; and
a pressure sensitive adhesive layer, in which the barrier layer is formed of a composition for forming a barrier layer, containing a monomer having a polymerizable group, and satisfies Conditions 1 and 2,
Condition 1: a functional group that reacts with a hydroxyl group to form a covalent bond is present on a surface of the barrier layer on a pressure sensitive adhesive layer side, and
Condition 2: no hydroxyl group other than the hydroxyl group included in the functional group is present in a region from the surface of the barrier layer on the pressure sensitive adhesive layer side to a half of a thickness of the barrier layer.
[2] The optical laminate according to [1],
in which the barrier layer does not exhibit liquid crystallinity.
[3] The optical laminate according to [1] or [2],
in which a monomer shrinkage amount S represented by the following expression is 0.1 or less,
Monomer shrinkage amount S=Thickness (μm) of barrier layer/Polymerizable group equivalent of monomer,
where the polymerizable group equivalent is calculated as [Molecular weight of monomer]/[Number of polymerizable groups per molecule of monomer].
[4] The optical laminate according to [3],
in which the monomer shrinkage amount S is 0.02 or less.
[5] The optical laminate according to any one of [1] to [4],
in which the film substrate consists of a cycloolefin-based polymer film.
[6] The optical laminate according to any one of [1] to [5], further comprising:
an optically anisotropic layer,
in which the optical laminate includes the optically anisotropic layer, the film substrate, the barrier layer, and the pressure sensitive adhesive layer in this order.
[7] A polarizing plate comprising:
a polarizer; and
the optical laminate according to any one of [1] to [6].
[8] An image display device comprising:
the optical laminate according to any one of [1] to [6] or the polarizing plate according to [7] [9]
[9] The image display device according to [8],
in which the image display device is a liquid crystal display device.
[10] The image display device according to [8],
in which the image display device is an organic electroluminescent display device.

According to the present invention, it is possible to provide an optical laminate having a barrier layer having excellent adhesiveness to a pressure sensitive adhesive layer, a polarizing plate, and an image display device.

### DESCRIPTION OF THE PREFERRED EMBODIMENTS

Hereinafter, the present invention will be described in detail.

Descriptions on the configuration requirements which will be described later are made based on representative embodiments of the present invention in some cases, but it should not be construed that the present invention is limited to such embodiments.

Furthermore, in the present specification, a numerical range expressed using “to” means a range including numerical values before and after “to” as a lower limit value and an upper limit value.

In addition, in the present specification, for each component, one kind of substance corresponding to each component may be used alone, or two or more kinds thereof may be used in combination. Here, in a case where the two or more kinds of the substances are used in combination for each component, the content of the component refers to a total content of the substances used in combination unless otherwise specified.

In addition, in the present specification, “(meth)acrylate” denotes “acrylate” or “methacrylate”, “(meth)acryl” denotes “acryl” or “methacryl”, and “(meth)acryloyl” denotes “acryloyl” or “methacryloyl”.

### [Optical Laminate]

The optical laminate of an embodiment of the present invention is an optical laminate having a film substrate, a barrier layer, and a pressure sensitive adhesive layer in this order, in which the barrier layer is formed of a composition for forming a barrier layer, containing a monomer having a polymerizable group, and satisfies Conditions 1 and 2.
Condition 1: A functional group that reacts with a hydroxyl group to form a covalent bond (hereinafter also simply referred to as a “specific functional group”) is present on a surface of the barrier layer on the pressure sensitive adhesive layer side.
Condition 2: No hydroxyl group other than the hydroxyl group included in the specific functional group is present in a region from the surface of the barrier layer on the pressure sensitive adhesive layer side to a half of a thickness of the barrier layer.

Here, with regard to Condition 1, “a surface of the barrier layer on the pressure sensitive adhesive layer side” refers to a surface layer region from the surface of the barrier layer on the pressure sensitive adhesive layer side to 20 nm in the thickness direction of the barrier layer, and is hereinafter also simply referred to as a “surface layer A”.

In addition, the presence of the specific functional group on the surface layer A of the barrier layer can be confirmed by, for example, time-of-flight secondary ion mass spectrometry (TOF-SIMS). The method described in “Surface Analysis Technology Library Secondary Ion Mass Spectrometry” edited by the Surface Science Society of Japan and published by Maruzen Co., Ltd. (1999) can be adopted as the TOF-SIMS.

In addition, with regard to Condition 1, examples of the above-described specific functional group include a boronic acid group, an isocyanate group, a silanol group, and a carboxyl group.

Among these, for a reason that a covalent bond can be easily formed, the boronic acid group, the isocyanate group, or the silanol group is preferable, and the boronic acid group is more preferable.

On the other hand, with regard to Condition 2, “the hydroxyl group included in the specific functional group” in the provision that “no hydroxyl group other than the hydroxyl group included in the specific functional group is present” means, for example, a case where the specific functional group is the boronic acid group (—B(OH)₂), and is not a provision intended to mean that the specific functional group necessarily includes the hydroxyl group.

In addition, in the region from the surface of the barrier layer on the pressure sensitive adhesive layer side to a half of the thickness of the barrier layer (hereinafter also simply referred to as a “specific region” in the present paragraph), a case where “no hydroxyl group other than the hydroxyl group included in the specific functional groups is present” can be confirmed by etching a sample from the side of the barrier layer opposite to the pressure sensitive adhesive layer side to the half of the thickness of the barrier layer by irradiation with ion beams, and then subjecting the remaining sample to transmission infrared spectroscopy (IR) measurement.

In the present invention, an optical laminate having a barrier layer with excellent adhesiveness to the pressure sensitive adhesive layer can be manufactured by configuring the barrier layer to satisfy Conditions 1 and 2 as described above.

A reason thereof is not specifically clear, but is presumed to be as follows by the present inventors.

First, it is considered that by satisfying Condition 1, it is possible to form a covalent bond by a reaction with a hydroxyl group and the like which may be present on the surface of the pressure sensitive adhesive layer.

Furthermore, it is considered that by satisfying Condition 2, the specific functional group can be effectively subjected to a reaction with a hydroxyl group and the like that may be present on the surface of the pressure sensitive adhesive layer without being deactivated in the barrier layer.

### [Film Substrate]

The optical laminate of the embodiment of the present invention includes a film substrate.

The film substrate is preferably transparent.

Here, the term “transparent” in the present specification denotes that a transmittance of visible light is 60% or more. In the present invention, the transmittance is preferably 80% or more, and more preferably 90% or more.

### Examples of the Film Substrate Include a Polymer Film.

Examples of a material for the polymer film include a cellulose-based polymer, a (meth)acrylic polymer, a polyester-based polymer, a cycloolefin-based polymer, and a polymer obtained by mixing two or more of these polymers.

In the present invention, a film substrate consisting of the cycloolefin-based polymer film is preferable since the effect of the present invention, that is, the effect of improving the adhesiveness with the pressure sensitive adhesive layer is evident.

Examples of the cycloolefin-based polymer include (1) a norbornene-based polymer, (2) a polymer of a monocyclic cycloolefin, (3) a polymer of a cyclic conjugated diene, (4) a vinyl alicyclic hydrocarbon polymer, and hydrides of (1) to (4).

A thickness of the film substrate is not particularly limited, but is preferably 30 μm or less, more preferably 5 μm to 30 μm, still more preferably 7 μm to 25 μm, and particularly preferably 10 μm to 20 μm.

### [Barrier Layer]

The optical laminate of the embodiment of the present invention has a barrier layer.

As described above, the barrier layer is a layer that is formed of a composition for forming a barrier layer, containing a monomer having a polymerizable group, and satisfies the above-described Conditions 1 and 2.

Hereinafter, each component of the composition for forming a barrier layer will be described.

### <Monomer>

The monomer included in the composition for forming a barrier layer is not particularly limited as long as it is a monomer having a polymerizable group.

Here, the polymerizable group is not particularly limited, and a radically polymerizable or cationically polymerizable group is preferable.

A known radically polymerizable group can be used as the radically polymerizable group, and suitable examples thereof include an acryloyloxy group or a methacryloyloxy group. In this case, it is known that the acryloyloxy group generally has a high polymerization rate, and from the viewpoint of improvement of productivity, the acryloyloxy group is preferable, but the methacryloyloxy group can also be used as the polymerizable group.

A known cationically polymerizable group can be used as the cationically polymerizable group, and specific examples thereof include an alicyclic ether group, a cyclic acetal group, a cyclic lactone group, a cyclic thioether group, a spiroorthoester group, and a vinyloxy group. Among these, the alicyclic ether group or the vinyloxy group is suitable, and an epoxy group, an oxetanyl group, or the vinyloxy group is particularly preferable.

Particularly preferred examples of the polymerizable group include a polymerizable group represented by any of Formulae (P-1) to (P-20).

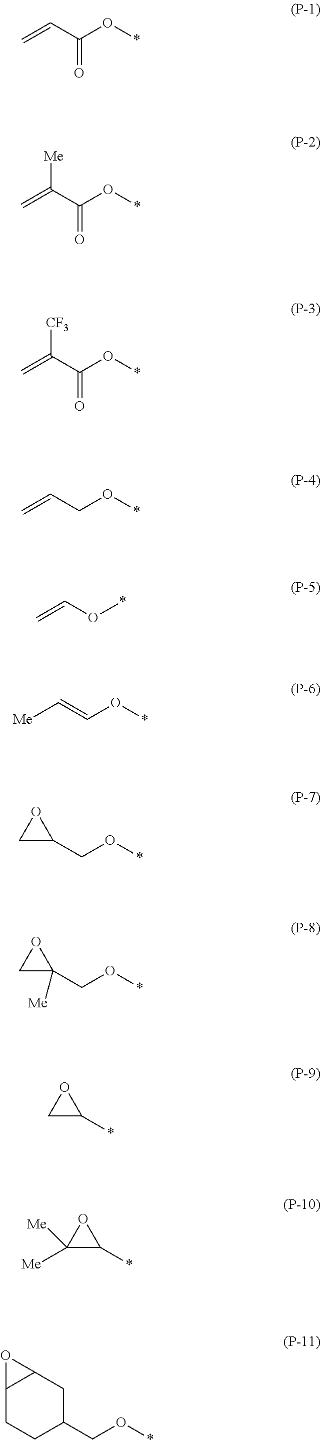

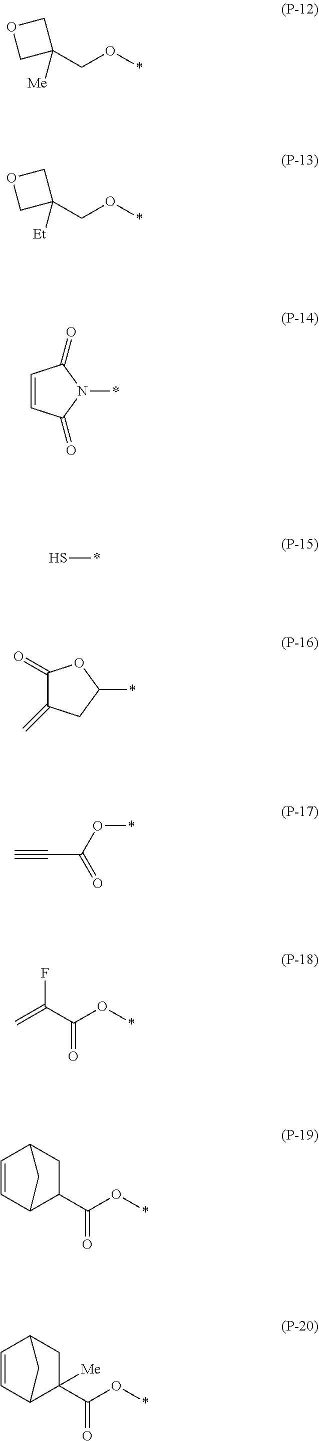

In the present invention, the monomer is preferably a polyfunctional monomer having two or more polymerizable groups, and more preferably a polyfunctional monomer having two or more acryloyloxy groups or methacryloyloxy groups. Furthermore, in the present invention, as the monomer, a monofunctional monomer may be used in combination with the polyfunctional monomer.

Examples of the bifunctional monomer among the polyfunctional monomers include 1,4-butanediol di(meth)acrylate, 1,6-hexanediol di(meth)acrylate, neopentyl glycol di(meth)acrylate, ethylene glycol di(meth)acrylate, triethylene glycol di(meth)acrylate, (meth)acrylic acid diesters of alkylene glycol, (meth)acrylic acid diesters of polyoxyalkylene glycol, and (meth)acrylic acid diesters of polyhydric alcohols.

Moreover, examples of the trifunctional monomers include trimethylolpropane triacrylate, trimethylolpropane propylene oxide (PO)-modified triacrylate, trimethylolpropane ethylene oxide (EO)-modified triacrylate, trimethylolpropane trimethacrylate, and pentaerythritol triacrylate.

In addition, examples thereof further include tetrafunctional or higher-functional monomers such as pentaerythritol tetraacrylate, pentaerythritol tetramethacrylate, dipentaerythritol pentaacrylate, dipentaerythritol pentamethacrylate, dipentaerythritol hexaacrylate, and dipentaerythritol hexamethacrylate.

The monofunctional monomer that can be used in combination with the polyfunctional monomer is not particularly limited, but from the viewpoint of the adhesiveness to the film substrate, suitable examples thereof include a compound having a polymerizable group and a boronic acid group (a boronic acid monomer).

Examples of such a boronic acid monomer include those described in paragraphs [0060] to [0073] of WO2020/045224A.

In the present invention, for a reason that it is easy to satisfy the above-described Condition 2, it is preferable to use a monomer having no hydroxyl group among the above-described monomers.

In the present invention, for a reason that the display performance of the image display device of an embodiment of the present invention which will be described later is improved, a monomer shrinkage amount S, which is represented by the following expression with respect to the monomer, is preferably 0.1 or less, and more preferably 0.02 or less.

Monomer shrinkage amount S=Thickness (μm) of barrier layer/Polymerizable group equivalent of monomer,

where the polymerizable group equivalent is calculated as [Molecular weight of monomer]/[Number of polymerizable groups per molecule of monomer].

### <Polymerization Initiator>

It is preferable that the composition for forming a barrier layer includes a polymerization initiator.

The polymerization initiator is not particularly limited, and examples thereof include a thermal polymerization initiator and a photopolymerization initiator, depending on a type of the polymerization reaction.

As the polymerization initiator, a photopolymerization initiator capable of initiating a polymerization reaction upon irradiation with ultraviolet rays is preferable.

Examples of the photopolymerization initiator include α-carbonyl compounds (described in each of the specifications of U.S. Pat. Nos. 2,367,661A and 2,367,670A), acyloin ethers (described in the specification of U.S. Pat. No. 2,448,828A), a-hydrocarbon-substituted aromatic acyloin compounds (described in the specification of U.S. Pat. No. 2,722,512A), multinuclear quinone compounds (described in each of the specifications of U.S. Pat. Nos. 3,046,127A and 2,951,758A), combinations of a triarylimidazole dimer and a p-aminophenyl ketone (described in the specification of U.S. Pat. No. 3,549,367A), acridine and phenazine compounds (described in JP1985-105667A (JP-S60-105667A) and the specification of U.S. Pat. No. 4,239,850A), oxadiazole compounds (described in the specification of U.S. Pat. No. 4,212,970A), and acyl phosphine oxide compounds (described in JP1988-040799B (JP-S63-040799B), JP1993-029234B (JP-H05-029234B), JP1998-095788A (JP-H10-095788A), and JP1998-029997A (JP-H10-029997A)).

As the polymerization initiator, an oxime-type polymerization initiator is also preferable. Specific examples thereof include the polymerization initiators described in paragraphs to of WO2017/170443A. As a commercially available oxime-type polymerization initiator, IRGACURE OXE01 (manufactured by BASF SE) or the like can be used.

In addition, in order to promote the polymerization reaction, it is also preferable to use two or more kinds of polymerization initiators having different absorption wavelengths of ultraviolet rays in combination.

In the present invention, in order to efficiently react the monomers to increase a degree of polymerization, it is preferable that the polymerization initiator is efficiently cleaved during ultraviolet (UV) curing to reduce the amount of the polymerization initiator remaining in the film after UV curing from the viewpoint of durability. With regard to the amount of the unreacted polymerization initiator, it is possible to quantify the amount of the remaining polymerization initiator per unit area of the film by immersing the barrier layer film in a tetrahydrofuran (THF) solvent to extract the polymerization initiator, and then performing analysis using high-performance liquid chromatography (HPLC). A smaller amount of the unreacted polymerization initiator is preferable, and the amount is preferably less than 0.1 mmol/m², more preferably less than 0.05 mmol/m², and still more preferably less than 0.02 mmol/m²

### <Leveling Agent>

The composition for forming a barrier layer preferably includes a leveling agent for a reason that it is easy to satisfy the above-described Condition 1.

Such a leveling agent is preferably a fluorine-based leveling agent or a silicon-based leveling agent for a reason that it has a high leveling effect on the addition amount, and the leveling agent is more preferably a fluorine-based leveling agent from the viewpoint that it is less likely to cause bleeding (bloom or bleed).

Examples of the leveling agent include the compounds described in paragraphs to of JP2007-069471A, the compound represented by General Formula (I) described in JP2013-047204A (in particular, the compounds described in paragraphs to [0032]), the compound represented by General Formula (I) described in JP2012-211306A (in particular, the compounds described in paragraphs to [0029]), the liquid crystal alignment accelerator represented by General Formula (I) described in JP2002-129162A (in particular, the compounds described in paragraphs to and to [0084]), the compounds represented by General Formulae (I), (II), and (III) described in JP2005-099248A (in particular, the compounds described in paragraphs to [0096]), the copolymers described in paragraphs to of WO2018/062068A, and the copolymers described in paragraphs to of WO2018/062077A. Furthermore, the contents of these publications are incorporated in the present specification.

### <Solvent>

The composition for forming a barrier layer preferably includes a solvent from the viewpoint of workability for forming a barrier layer.

Examples of the solvent include ketones (for example, acetone, 2-butanone, methyl isobutyl ketone, cyclopentanone, and cyclohexanone), ethers (for example, dioxane, tetrahydrofuran, and propylene glycol monomethyl ether acetate (PGMEA)), aliphatic hydrocarbons (for example, hexane), alicyclic hydrocarbons (for example, cyclohexane), aromatic hydrocarbons (for example, toluene, xylene, and trimethylbenzene), halogenated carbons (for example, dichloromethane, dichloroethane, dichlorobenzene, and chlorotoluene), esters (for example, methyl acetate, ethyl acetate, and butyl acetate), water, alcohols (for example, ethanol, isopropanol, butanol, and cyclohexanol), cellosolves (for example, methyl cellosolve and ethyl cellosolve), cellosolve acetates, sulfoxides (for example, dimethyl sulfoxide), and amides (for example, dimethylformamide and dimethylacetamide).

The solvents may be used alone or in combination of two or more kinds thereof.

A method for forming a barrier layer using the composition for forming a barrier layer is not particularly limited, but examples thereof include a method of applying the composition for forming a barrier layer onto the above-described film substrate to form a coating film to carry out a curing treatment.

The application can be carried out by a known method (for example, a wire bar coating method, an extrusion coating method, a direct gravure coating method, a reverse gravure coating method, and a die coating method).

Examples of the curing treatment for the coating film include known methods. Energy ray irradiation, a light irradiation treatment, or a heating treatment is preferable, and the light irradiation treatment is particularly preferable.

During the light irradiation treatment, ultraviolet rays are preferably used.

Conditions for the light irradiation treatment are not particularly limited, but are preferably 10 mJ/cm² to 50 J/cm², and more preferably 20 mJ/cm² to 5 J/cm².

In addition, the light irradiation treatment may be carried out under a heating condition in order to accelerate the polymerization reaction.

In the present invention, it is preferable that the barrier layer does not exhibit liquid crystallinity for a reason that the display performance in the image display device of the embodiment of the present invention which will be described later is improved.

Here, it can be confirmed that the barrier layer does not exhibit liquid crystallinity by observation with a polarization microscope. Specifically, a sample that has been exposed by etching through irradiation with ion beams is manufactured, polarizers are disposed above and below the sample in a state where the absorption axes are orthogonal to each other, then the sample is rotated by 0 to 90 degrees. In a case where a bright field of view is confirmed in either the scope observation or the conoscopic observation, it can be determined that the sample exhibits liquid crystallinity.

The thickness of the barrier layer is not particularly limited, but is preferably 0.2 μm or more, and more preferably 0.5 μm or more. The upper limit is not particularly limited, but is preferably 10 μm or less, more preferably 8 μm or less, and still more preferably 5 μm or less from the viewpoint of ensuring the flexibility of the optical laminate.

In the present invention, an oxygen permeability coefficient of the barrier layer is preferably 30% or less, more preferably 20% or less, and still more preferably 10% or less of the oxygen permeability coefficient of the film substrate.

Here, the oxygen permeability coefficient can be determined by a measurement according to JIS K7126-1.

In the present invention, from the viewpoint of durability, it is preferable to use a barrier layer having a low oxygen permeability coefficient. Furthermore, in order to realize a barrier layer having a low oxygen permeability coefficient, it is preferable that the monomers (non-bonded low-molecular-weight components and the like) and non-bonded polymerizable groups, remaining in the film after UV curing, are reduced to efficiently react the monomers, thus increasing the degree of polymerization.

With regard to the amount of the unreacted monomers (residual monomers in the barrier layer), the amount of the remaining monomers per unit area of the film can be quantified by analysis using high performance liquid chromatography (HPLC) after immersing the barrier layer film in a THF solvent (using a solvent capable of eluting a target monomer) to extract the monomers. A smaller amount of the unreacted monomers (the residual monomers in the barrier layer) is preferable, and specifically, the amount is preferably less than 0.1 mmol/m², more preferably less than 0.02 mmol/m², and still more preferably less than 0.01 mmol/m².

With regard to the non-bonded polymerizable group, the amount of the remaining double bonds can be determined by the following infrared absorption measurement. For example, in a case where an acrylate is used as the monomer of the barrier layer and in a case of a polymerization reaction with a (meth)acryloyloxy group, an infrared absorption peak surface area A near 810 cm⁻¹ due to a carbon-carbon double bond (C═C) of a (meth)acryloyloxy group in the barrier layer after finishing coating, and an infrared absorption peak surface area B near 1,720 cm⁻¹ due to an acyl group (C═O) are measured before and after the polymerization reaction, and an residual amount of the remaining non-bonded (meth)acryloyloxy group can be calculated by [(A/B after polymerization/(A/B before polymerization)]×100. A content of the non-bonded polymerizable group is preferably less than 50%, more preferably less than 35%, and still more preferably less than 25%.

### [Pressure Sensitive Adhesive Layer]

The optical laminate of the embodiment of the present invention includes a pressure sensitive adhesive layer.

The pressure sensitive adhesive included in the pressure sensitive adhesive layer is preferably a pressure sensitive adhesive in which a hydroxyl group is present on the surface in a case of being formed into the pressure sensitive adhesive layer, and examples thereof include a rubber-based pressure sensitive adhesive, an acrylic pressure sensitive adhesive, a silicone-based pressure sensitive adhesive, a urethane-based pressure sensitive adhesive, a vinyl alkyl ether-based pressure sensitive adhesive, a polyvinyl alcohol-based pressure sensitive adhesive, a polyvinylpyrrolidone-based pressure sensitive adhesive, a polyacrylamide-based pressure sensitive adhesive, and a cellulose-based pressure sensitive adhesive.

Among those, the acryl-based pressure sensitive adhesive (adhesive that is sensitive to a pressure) is preferable from the viewpoints of transparency, weather fastness, heat resistance, and the like.

As the acrylic pressure sensitive adhesive, a (meth)acrylic polymer is used and a main component thereof contains alkyl (meth)acrylate as a monomer unit.

Examples of the alkyl (meth)acrylate constituting the main skeleton of the (meth)acrylic polymer include a linear or branched alkyl group having 1 to 18 carbon atoms. These can be used alone or in combination thereof. The average number of carbon atoms of these alkyl groups is preferably in a range of 3 to 9. In addition, alkyl (meth)acrylate having an aromatic ring, such as phenoxyethyl (meth)acrylate and benzyl (meth)acrylate, can be used. The alkyl (meth)acrylate having an aromatic ring may be used by mixing a polymer obtained by polymerizing the alkyl (meth)acrylate with the (meth)acrylic polymer exemplified above or by copolymerizing the polymer with the alkyl (meth)acrylate. From the viewpoint of transparency, copolymerization is preferable.

The details of the pressure sensitive adhesive are described in, for example, paragraphs to of JP2018-60014A. The description of the document is incorporated in the present specification by reference.

In the present invention, from the viewpoint that the durability is improved, the residual amount of the (meth)acrylic acid ester-based monomer having a cyclic structure in the pressure sensitive adhesive layer is preferably 100 ppm or less.

In addition, also in a case where the (meth)acrylic acid ester-based monomer having a cyclic structure is used as the monomer of the barrier layer, the residual amount is preferably 100 ppm or less.

A method of forming the pressure sensitive adhesive layer is not particularly limited, and the pressure sensitive adhesive layer can be formed by, for example, a method of applying a solution of a pressure sensitive adhesive onto a release sheet, drying the solution, and then transferring the sheet to a surface of a transparent resin layer; a method of directly applying a solution of a pressure sensitive adhesive onto a surface of a transparent polymer layer and drying the solution; or the like.

For example, the solution of the pressure-sensitive adhesive is prepared as a solution of about 10% to 40% by mass in which the pressure sensitive adhesive is dissolved or dispersed in a solvent such as toluene and ethyl acetate.

As the application method, a roll coating method such as reverse coating or gravure coating, a spin coating method, a screen coating method, a fountain coating method, a dipping method, and a spraying method can be employed.

It should be noted that from the viewpoint of suppressing chemical cracks of the cycloolefin-based polymer, it is preferable to dry the solvent so as not to remain.

Examples of the constituent material of the release sheet include appropriate thin paper bodies, for example, synthetic polymer films such as polyethylene, polypropylene, and polyethylene terephthalate, rubber sheets, paper, cloth, nonwoven fabrics, nets, foam sheets, and metal foils.

A thickness of the pressure sensitive adhesive layer is not particularly limited, but is preferably in a range of 3 μm to 50 μm, more preferably in a range of 4 μm to 50 μm, still more preferably in a range of 5 μm to 50 μm, and particularly preferably in a range of 5 μm to 30 μm from the viewpoint that the durability is improved.

Furthermore, from the viewpoint that the durability is improved, a storage elastic modulus of the pressure sensitive adhesive layer is preferably 0.18 MPa or more, more preferably 0.45 MPa or more, and still more preferably 2.2 MPa or more. In addition, from the viewpoint of peeling properties, the storage elastic modulus of the pressure sensitive adhesive layer is preferably 5 MPa or less.

Here, the storage elastic modulus of the pressure sensitive adhesive layer denotes a value measured by a tensile tester using the following method after the pressure sensitive adhesive is laminated.

For the measurement, a plurality of pressure sensitive adhesive tapes are laminated and bonded to each other, and autoclaved at 60° C. and 0.5 MPa for 30 minutes to manufacture a sample for a dynamic viscoelasticity test with a thickness of 1 mm.

This sample is subjected to a dynamic viscoelasticity test in a linear region under the conditions of a frequency of 1 Hz using a tensile tester (shear type rheometer (device name: MCR301, manufactured by Anton Paar GmbH)).

Next, the storage elastic modulus is measured by reading a value at 30° C. under the conditions of a temperature rising rate of 3° C./min in a temperature range of −40° C. to +150° C.

As described above, the optical laminate of the embodiment of the present invention is a laminate including the film substrate, the barrier layer, and the pressure sensitive adhesive layer, each described above, in this order, but is preferably a laminate having the film substrate, the barrier layer, and the pressure sensitive adhesive layer, each described above, in this order, which are adjacent to each other.

### [Optically Anisotropic Layer]

For a reason that the viewing angle of a display device is improved, the optical laminate of the embodiment of the present invention preferably has an optically anisotropic layer, and more preferably includes an optically anisotropic layer, and the film substrate, the barrier layer, and the pressure sensitive adhesive layer, each described above, in this order.

It is preferable that the optically anisotropic layer is formed of a liquid crystal composition containing a liquid crystal compound (hereinafter also simply referred to as a “composition for forming an optically anisotropic layer”).

In the optically anisotropic layer, it is preferable that the molecules of the liquid crystal compound are fixed in a state of a smectic phase or a nematic phase in homogeneous alignment.

### <Liquid Crystal Compound>

The liquid crystal compound contained in the composition for forming an optically anisotropic layer is a liquid crystal compound having a polymerizable group.

In general, the liquid crystal compounds can be classified into rod-like type ones and disk-like type ones according to the shapes thereof. Each of the types can further be classified into a low-molecular-weight type and a high-molecular-weight type. The term, high-molecular-weight, generally refers to having a degree of polymerization of 100 or more (Polymer Physics-Phase Transition Dynamics, by Masao Doi, page 2, published by Iwanami Shoten, Publishers, 1992).

In the present invention, any of liquid crystal compounds can be used, but a rod-shaped liquid crystal compound or a discotic liquid crystal compound (disk-shaped liquid crystal compound) is preferably used, and the rod-shaped liquid crystal compound is more preferably used.

In the present invention, a liquid crystal compound having a polymerizable group is used in order to immobilize the above-described liquid crystal compound, but it is more preferable that the liquid crystal compound has two or more polymerizable groups in one molecule. Moreover, in a case where the liquid crystal compound is a mixture of two or more kinds thereof, it is preferable that at least one kind of the liquid crystal compounds has two or more polymerizable groups in one molecule. Furthermore, after the liquid crystal compound is immobilized by polymerization, it is no longer necessary to exhibit liquid crystallinity.

In addition, the type of the polymerizable group is not particularly limited, and examples thereof include the same ones as the polymerizable groups contained in the monomer included in the composition for forming a barrier layer described above.

As the rod-like liquid crystal compound, for example, the rod-like liquid crystal compounds described in claim 1 of JP1999-513019A (JP-H11-513019A) or paragraphs [0026] to [0098] of JP2005-289980A can be preferably used, and as the discotic liquid crystal compound, for example, the discotic liquid crystal compounds described in paragraphs [0020] to [0067] of JP2007-108732A and paragraphs to of JP2010-244038A can be preferably used, but the rod-like liquid crystal compounds and the discotic liquid crystal compounds are not limited thereto.

Moreover, in the present invention, a liquid crystal compound with reverse wavelength dispersibility can be used as the liquid crystal compound.

Here, in the present specification, the liquid crystal compound having “reverse wavelength dispersibility” denotes that in the measurement of an in-plane phase difference (Re) value at a specific wavelength (visible light range) of a phase difference film manufactured using the liquid crystal compound, the Re value is the same or increased as the measurement wavelength increases.

In addition, the liquid crystal compound with reverse wavelength dispersibility is not particularly limited as long as a film having reverse wavelength dispersibility can be formed as described above, and examples thereof include the compound represented by General Formula (1) described in JP2010-084032A (particularly the compound described in paragraphs [0067] to [0073]), the compound represented by General Formula (II) described in JP2016-053709A (particularly the compound described in paragraphs [0036] to [0043]), and the compound represented by General Formula (1) described in JP2016-081035A (particularly the compound described in paragraphs [0043] to [0055]).

### <Alignment Control Agent>

The composition for forming an optically anisotropic layer may include an alignment control agent, as necessary.

With the alignment control agent, various alignment states such as homeotropic alignment (vertical alignment), tilt alignment, hybrid alignment, and cholesteric alignment can be formed, in addition to the homogeneous alignment, and specific alignment states can be controlled and realized more uniformly and more accurately.

As an alignment control agent that accelerates the homogeneous alignment, for example, a low-molecular-weight alignment control agent and a high-molecular-weight alignment control agent can be used.

With regard to the low-molecular-weight alignment control agent, reference can be made to the description in, for example, paragraphs [0009] to [0083] of JP2002-20363A, paragraphs [0111] to [0120] of JP2006-106662A, and paragraphs [0021] to [0029] of JP2012-211306A, the contents of which are hereby incorporated by reference.

In addition, with regard to the high-molecular-weight alignment control agent, reference can be made to the description in, for example, paragraphs [0021] to [0057] of JP2004-198511A and paragraphs [0121] to [0167] of JP2006-106662A, the contents of which are hereby incorporated by reference.

Moreover, examples of an alignment control agent that forms or accelerates the homeotropic alignment include a boronic acid compound and an onium salt compound. With regard to the alignment control agent, reference can be made to the description in the compounds described in paragraphs [0023] to [0032] of JP2008-225281A, paragraphs [0052] to [0058] of JP2012-208397A, paragraphs [0024] to [0055] of JP2008-026730A, and paragraphs [0043] to [0055] of JP2016-193869A, the contents of which are hereby incorporated by reference.

On the other hand, the cholesteric alignment can be realized by adding a chiral agent to the composition for forming an optically anisotropic layer of the embodiment of the present invention, and it is possible to control a direction of revolution of the cholesteric alignment by its chiral direction.

Incidentally, a pitch of the cholesteric alignment may be controlled in accordance with the alignment restricting force of the chiral agent.

### <Other Components>

The composition for forming an optically anisotropic layer may contain components other than the above-described components. Examples of the other components include the polymerization initiator, the leveling agent, and the solvent, each described in the above-described composition for forming a barrier layer.

Examples of a method for forming the optically anisotropic layer include a method in which the above-described composition for forming an optically anisotropic layer is used to form a desired alignment state, which is then immobilized by polymerization.

Here, the polymerization conditions are not particularly limited, but in the polymerization by irradiation with light, ultraviolet rays are preferably used. The irradiation dose is preferably 10 mJ/cm² to 50 J/cm², more preferably 20 mJ/cm² to 5 J/cm², still more preferably 30 mJ/cm² to 3 J/cm², and particularly preferably 50 to 1,000 mJ/cm². In addition, the polymerization may be carried out under a heating condition in order to accelerate the polymerization reaction.

The alignment state of the liquid crystal compound in the optically anisotropic layer may be any of horizontal alignment, vertical alignment, tilt alignment, and twist alignment, and it is preferable that the rod-shaped liquid crystal compound is immobilized in a state of being horizontally aligned with respect to the main surface of the optically anisotropic layer.

Furthermore, in the present specification, the “horizontal alignment” means that the main surface of the optically anisotropic layer (or the surface of the film substrate) and the major axis direction of the liquid crystal compound are parallel to each other. Incidentally, it is not required for the both to be strictly parallel, and in the present specification, the expression means that the both are aligned at an angle formed by the major axis direction of the liquid crystal compound and the main surface of the optically anisotropic layer of less than 10°.

In the optically anisotropic layer, an angle formed by the major axis direction of the liquid crystal compound and the main surface of the optically anisotropic layer is preferably 0° to 5°, more preferably 0° to 3°, and still more preferably 0° to 2°.

In the present invention, the optically anisotropic layer of the embodiment of the present invention is preferably a positive A plate or a positive C plate, and more preferably the positive C plate.

Here, the positive A plate (A plate which is positive) and the positive C plate (C plate which is positive) are defined as follows.

In a case where a refractive index in a film in-plane slow axis direction (in a direction in which an in-plane refractive index is maximum) is defined as nx, a refractive index in an in-plane direction orthogonal to the in-plane slow axis is defined as ny, and a refractive index in a thickness direction is defined as nz, the positive A plate satisfies the relationship of Expression (A1) and the positive C plate satisfies the relationship of Expression (C1). Furthermore, the positive A plate has an Rth showing a positive value and the positive C plate has an Rth showing a negative value.

$$nx > ny \approx nz \qquad Expression ( A 1 )$$

$$nz > nx \approx ny \qquad Expression ( C 1 )$$

Furthermore, the symbol, “≈”, encompasses not only a case where the both sides are completely the same as each other but also a case where the both are substantially the same as each other.

In the expression, “substantially the same”, with regard to the positive A plate, for example, a case where (ny-nz)×d (in which d is the thickness of a film) is −10 to 10 nm, and preferably −5 to 5 nm is also included in “ny≈nz”, and a case where (nx-nz)×d is −10 to 10 nm, and preferably −5 to 5 nm is also included in “nx≈nz”. In addition, with regard to the positive C plate, for example, a case where (nx-ny)×d (in which d is the thickness of a film) is 0 to 10 nm, and preferably 0 to 5 nm is also included in “nx≈ny”.

A thickness of the optically anisotropic layer is not particularly limited, but is preferably 0.1 μm or more, and more preferably 0.2 μm or more. The upper limit is not particularly limited, but is preferably 10 μm or less, and more preferably 8 μm or less from the viewpoint of ensuring the flexibility of the optical laminate.

### [Polarizing Plate]

The polarizing plate of an embodiment of the present invention is a polarizing plate having a polarizer and the above-described optical laminate of the embodiment of the present invention.

### [Polarizer]

The polarizer contained in the polarizing plate of the embodiment of the present invention is not particularly limited as long as it is a member having a function of converting light into specific linearly polarized light, and an absorptive type polarizer and a reflective type polarizer, which are known in the related art, can be used.

An iodine-based polarizer, a dye-based polarizer using a dichroic dye, a polyene-based polarizer, or the like is used as the absorptive type polarizer. The iodine-based polarizer and the dye-based polarizer are classified into a coating type polarizer and a stretching type polarizer, any of which can be applied, but a polarizer manufactured by allowing polyvinyl alcohol to adsorb iodine or a dichroic dye and performing stretching is preferable.

In addition, examples of a method for obtaining a polarizer by carrying out stretching and dying in a state of a laminated film in which a polyvinyl alcohol layer is formed on a substrate include those described in JP5048120B, JP5143918B, JP4691205B, JP4751481B, and JP4751486B, and known technology relating to these polarizers can also be preferably used.

A polarizer in which thin films having different birefringence are laminated, a wire grid-type polarizer, a polarizer having a combination of a cholesteric liquid crystal having a selective reflection range, and a ¼ wavelength plate, or the like is used as the reflective type polarizer.

Among those, a polarizer including a polyvinyl alcohol-based resin (a polymer including —CH₂—CHOH— as a repeating unit, in particular, at least one selected from the group consisting of a polyvinyl alcohol and an ethylene-vinyl alcohol copolymer) is preferable from the viewpoint that it has more excellent adhesiveness.

In the present invention, a thickness of the polarizer is not particularly limited, but is preferably 3 μm to 60 μm, more preferably 3 μm to 30 μm, and still more preferably 3 μm to 10 μm.

### [Image Display Device]

The image display device of the embodiment of the present invention is an image display device having the optical laminate of the embodiment of the present invention or the polarizing plate of the embodiment of the present invention.

A display element used in the image display device of the embodiment of the present invention is not particularly limited, and examples thereof include a liquid crystal cell, an organic electroluminescent (hereinafter simply referred to as “EL”) display panel, and a plasma display panel.

Among those, the liquid crystal cell and the organic EL display panel are preferable, and the liquid crystal cell is more preferable. That is, as the image display device of the embodiment of the present invention, a liquid crystal display device using a liquid crystal cell as a display element or an organic EL display device using an organic EL display panel as a display element is preferable, and the liquid crystal display device is more preferable.

### [Liquid Crystal Display Device]

A liquid crystal display device which is an example of the image display device of the embodiment of the present invention is a liquid crystal display device having the above-described polarizing plate of the embodiment of the present invention and a liquid crystal cell.

Furthermore, in the present invention, it is preferable that the polarizing plate of the embodiment of the present invention is used as the polarizing plate on the front side, and it is more preferable that the polarizing plate of the embodiment of the present invention is used as the polarizing plates on the front and rear sides, among the polarizing plates provided on the both sides of the liquid crystal cell.

Hereinafter, the liquid crystal cell constituting the liquid crystal display device will be described in detail.

### <Liquid Crystal Cell>

The liquid crystal cell used for the liquid crystal display device is preferably in a vertical alignment (VA) mode, an optically compensated bend (OCB) mode, an in-plane-switching (IPS) mode, a fringe-field-switching (FFS) mode, or a twisted nematic (TN) mode, but is not limited thereto.

In a TN-mode liquid crystal cell, rod-shaped liquid crystal molecules are substantially horizontally aligned and are twist-aligned at 60° to 120° during no voltage application thereto. The TN-mode liquid crystal cell is most often used in a color TFT liquid crystal display device, and described in numerous documents.

In a VA-mode liquid crystal cell, rod-shaped liquid crystal molecules are substantially vertically aligned during no voltage application thereto. Examples of the VA-mode liquid crystal cell include (1) a VA-mode liquid crystal cell in the narrow sense of the word, in which rod-shaped liquid crystal molecules are substantially vertically aligned during no voltage application thereto, but are substantially horizontally aligned during voltage application thereto (described in JP1990-176625A (JP-H02-176625A)), (2) an MVA-mode liquid crystal cell in which the VA-mode is multi-domained for viewing angle enlargement (described in SID97, Digest of Tech. Papers (preprint), 28 (1997) 845), (3) a liquid crystal cell in a mode (n-ASM mode) in which rod-shaped liquid crystal molecules are substantially vertically aligned during no voltage application thereto and are twistedly multi-domain-aligned during voltage application thereto (described in Seminar of Liquid Crystals of Japan, Papers (preprint), 58-59 (1998)), and (4) a survival-mode liquid crystal cell (announced in LCD International 98). In addition, the liquid crystal cell may be of any of a patterned vertical alignment (PVA) type, an optical alignment type, and a polymer-sustained alignment (PSA). Details of these modes are specifically described in JP2006-215326A and JP2008-538819A.

In an IPS-mode liquid crystal cell, rod-shaped liquid crystal molecules are aligned substantially parallel with respect to a substrate, and application of an electric field parallel to the substrate surface causes the liquid crystal molecules to respond planarly. The IPS-mode displays black in a state where no electric field is applied and a pair of upper and lower polarizing plates have absorption axes which are orthogonal to each other. A method of improving the viewing angle by reducing light leak during black display in an oblique direction using an optical compensation sheet is disclosed in JP1998-54982A (JP-H10-54982A), JP1999-202323A (JP-H11-202323A), JP1997-292522A (JP-H09-292522A), JP1999-133408A (JP-H11-133408A), JP1999-305217A (JP-H11-305217A), JP1998-307291A (JP-H10-307291A), and the like.

### [Organic EL Display Device]

Suitable examples of the organic EL display device which is an example of the image display device of the embodiment of the present invention include an aspect which includes, from the visible side, a polarizer, a N4 plate (a positive A plate) including the optically anisotropic layer of the embodiment of the present invention, and an organic EL display panel in this order.

In addition, the organic EL display panel is a display panel composed of an organic EL device in which an organic light emitting layer (organic electroluminescent layer) is sandwiched between electrodes (between a cathode and an anode). The configuration of the organic EL display panel is not particularly limited but a known configuration is adopted.

### EXAMPLES

Hereinbelow, the present invention will be described in more detail with reference to Examples. The materials, the amounts of materials used, the proportions, the treatment details, the treatment procedure, and the like shown in Examples below can be appropriately modified as long as the modifications do not depart from the spirit of the present invention. Therefore, the scope of the present invention should not be construed as being limited to Examples shown below.

### Example 1

### <Film Substrate>

A cycloolefin polymer film (Re=125 nm, Rth=63 nm, manufactured by JSR Corporation) was used as the film substrate.

### <Formation of Optically Anisotropic Layer>

A single surface of a cycloolefin polymer film (Re=125 nm, Rth=63 nm, manufactured by JSR Corporation) was subjected to a corona treatment at a discharge amount of 125 W·min/m², and a polymerizable liquid crystal composition 1 prepared with the following composition was applied onto the surface which had been subjected to the corona treatment, using a #3.0 wire bar.

Next, in order to dry the solvent in the composition and to mature the alignment of the liquid crystal compound, the film was heated with hot air at 70° C. for 90 seconds and irradiated with ultraviolet rays (300 mJ/cm²) at 40° C. at an oxygen concentration of 0.1% under a nitrogen purge, the alignment of the liquid crystal compound was immobilized to form an optically anisotropic layer, and a laminate 1 in which the optically anisotropic layer and the film substrate were laminated in this order was prepared.

In a case where a phase difference of the obtained laminate 1 was measured, an in-plane phase difference Re (550) was 125 nm and a retardation Rth (550) in the thickness direction was −25 nm. In addition, Re (450)/Re (550) was 1.01 and Rth (450)/Rth (550) was 1.06.

Polymerizable Liquid Crystal Composition 1

| | |
|---|---|
| The following liquid crystal compound L1 | 100.0 parts by mass |
| The following photopolymerization initiator S1 | 5.0 parts by mass |
| The following photopolymerization initiator S2 | 2.0 parts by mass |
| The following alignment assistant A1 | 2.0 parts by mass |
| The following compound B1 | 4.5 parts by mass |
| The following Compound C1 (A-TMMT, manufactured by Shin-Nakamura Chemical Co., Ltd.) | 8.0 parts by mass |
| The following leveling agent P1 | 0.4 parts by mass |
| The following leveling agent P2 | 0.5 parts by mass |
| Acetone | 426.0 parts by mass |
| PGMEA | 49.0 parts by mass |
| Methanol | 14.7 parts by mass |

Liquid crystal compound L1
Mixture of the following liquid crystal compounds (RA), (RB), and (RC) at a ratio of 83:15:2 (mass ratio) 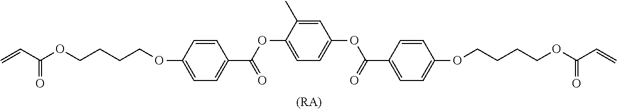 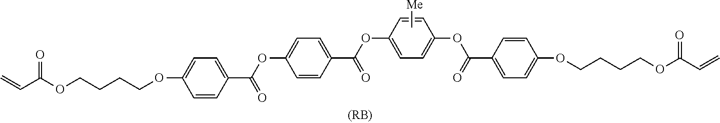 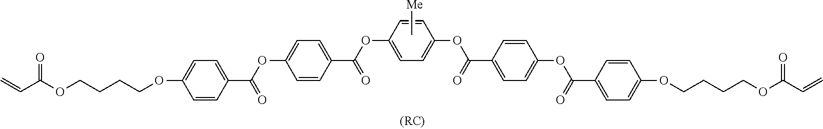
Photopolymerization initiator S1 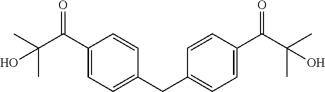 [SMILES: CC(C)(O)C(=O)c1ccc(Cc2ccc(C(=O)C(C)(C)O)cc2)cc1]
Photopolymerization initiator S2 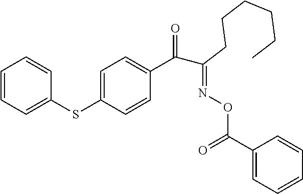 [SMILES: CCCCCC/C(=N\OC(=O)c1ccccc1)C(=O)c1ccc(Sc2ccccc2)cc1]
Alignment aid A1 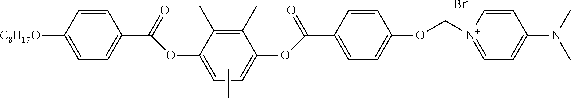
Compound B1 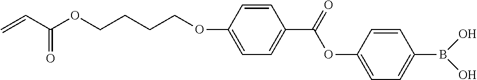 [SMILES: C=CC(=O)OCCCCOc1ccc(C(=O)Oc2ccc(B(O)O)cc2)cc1]
Compound C1 (A-TMMT, manufactured by Shin-Nakamura Chemical Co., Ltd.) 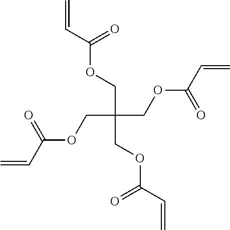 [SMILES: C=CC(=O)OCC(COC(=O)C=C)(COC(=O)C=C)COC(=O)C=C]
Leveling agent P1 <weight-average molecular weight: 15,000, the numerical values in the following formulae indicate contents (% by mass) of the respective repeating units with respect to all the repeating units> 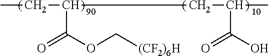
Leveling agent P2 <weight-average molecular weight: 11,000, the numerical values in the following formulae indicate contents (% by mole) of the respective repeating units with respect to all the repeating units>

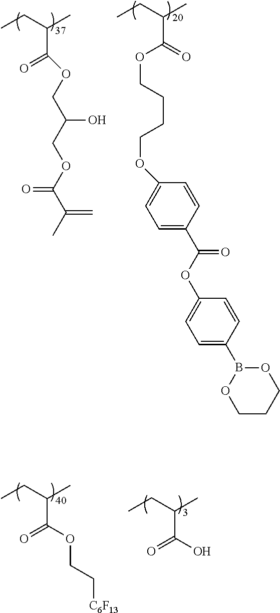

### <Formation of Barrier Layer>

A surface of the film substrate in the manufactured laminate 1 opposite to the optically anisotropic layer was subjected to a corona treatment at a discharge amount of 125 W·min/m², and a composition 1 for forming a barrier layer prepared with the following composition was applied onto the surface which had been subjected to the corona treatment, using a #3.0 wire bar.

Next, in order to dry the solvent of the composition, the laminate was heated with hot air at 70° C. for 90 seconds and then irradiated with ultraviolet rays (300 mJ/cm²) at 40° C. and an oxygen concentration of 0.1% under a nitrogen purge to form a barrier layer, and a laminate 2 in which the optically anisotropic layer, the film substrate, and the barrier layer were laminated in this order was manufactured.

In a case where a phase difference of the obtained laminate 2 was measured, an in-plane phase difference Re (550) was 125 nm and a retardation Rth (550) in the thickness direction was −25 nm. In addition, Re (450)/Re (550) was 1.01, Rth (450)/Rth (550) was 1.06, and the phase difference changes A from the laminate 1 were ΔRe=0 nm and ΔRth=0 nm.

Composition 1 for Forming Barrier Layer

| | |
|---|---|
| The following monomer 1 (A-TMMT, manufactured by Shin-Nakamura Chemical Co., Ltd.) | 71.8 parts by mass |
| The following monomer 2 (A-600, manufactured by Shin-Nakamura Chemical Co., Ltd.) | 23.9 parts by mass |
| The compound B1 | 4.3 parts by mass |
| The photopolymerization initiator S1 | 5.0 parts by mass |
| The following leveling agent P3 | 0.5 parts by mass |
| Acetone | 382.8 parts by mass |
| PGMEA | 44.0 parts by mass |
| Methanol | 13.2 parts by mass |

Monomer 1 (A-TMMT, manufactured by Shin-Nakamura Chemical Co., Ltd.) 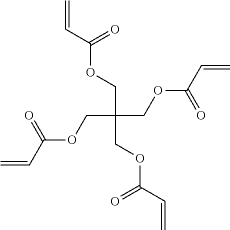 [SMILES: C=CC(=O)OCC(COC(=O)C=C)(COC(=O)C=C)COC(=O)C=C]
Monomer 2 (A-600, manufactured by Shin-Nakamura Chemical Co., Ltd.) 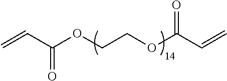
Leveling agent P3 <weight-average molecular weight: 11,000, the numerical values in the following formulae indicate contents (% by mole) of the respective repeating units with respect to all the repeating units>

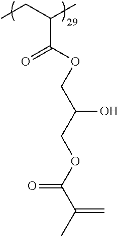

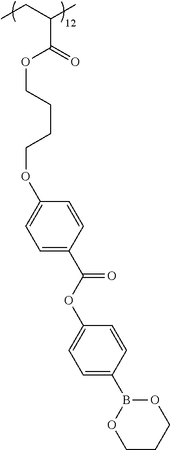

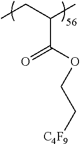

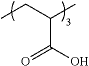

### <Formation of Pressure Sensitive Adhesive Layer (Manufacture of Optical Laminate)>

SK1478 (thickness: 25 μm, manufactured by Soken Chemical Co., Ltd.) as a pressure sensitive adhesive layer was bonded to a surface of the barrier layer in the manufactured laminate 2, and an optical laminate 1 in which the optically anisotropic layer, the film substrate, the barrier layer, and the pressure sensitive adhesive layer were laminated in this order was manufactured.

### Examples 2 to 10 and Comparative Examples 1 to 3

An optical laminate was manufactured in the same manner as in Example 1, except that the monomer 1, the monomer 2, and the leveling agent included in the composition for forming a barrier layer were changed to the compounds listed in Table 2.

The optical laminates manufactured in Examples 1 to 10 and Comparative Examples 1 to 3 were evaluated for adhesiveness and display performance described below. The results are shown in Table 2 below.

Furthermore, in Table 2, in the columns of the conditions 1 and 2, a case where the conditions are satisfied is denoted as “A”, and a case where the conditions are not satisfied is denoted as “B”.

In addition, whether the barrier layers of the optical laminates manufactured in Examples 1 to 10 and Comparative Examples 1 to 3 exhibited liquid crystallinity was confirmed according to the above-described method. As a result, it was confirmed that the barrier layers other than that in Example 9 did not exhibit liquid crystallinity.

### [Adhesiveness]

The manufactured optical laminate was cut into a size of 150 mm×25 mm in the slow axis direction, and only the portion in 80 mm×25 mm was bonded to a glass substrate through an adhesive (SK1478, manufactured by Soken Kagaku Co., Ltd.). The peel strength at the time of peeling in the 90° direction was measured with a Tensilon universal material tester (manufactured by Orientec Co., Ltd.) and evaluated according to the following standard.

### (Evaluation Standard)

A: 4.0 N/25 mm or more
B: 2.0 N/25 mm or more and less than 4.0 N/25 mm
C: Less than 2.0 N/25 mm

### [Display Performance]

### [Manufacture of Protective Film 1]

### <Preparation of Core Layer Cellulose Acylate Dope 1>

The following composition was put into a mixing tank and stirred to dissolve the respective components to prepare a core layer cellulose acylate dope 1.

Core layer cellulose acylate dope 1

| | |
|---|---|
| Cellulose acetate having a degree of acetyl | 100 parts by mass |
| substitution of 2.88 | |
| Ester oligomer (the following compound 1-1) | 10 parts by mass |
| Durability improver (the following compound 1-2) | 4 parts by mass |
| Ultraviolet absorber (the following compound 1-3) | 3 parts by mass |
| Methylene chloride (the first solvent) | 438 parts by mass |
| Methanol (the second solvent) | 65 parts by mass |

Compound 1-1 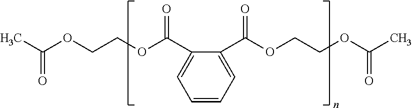
Compound 1-2 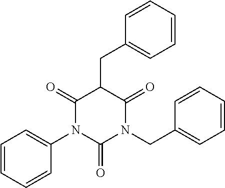 [SMILES: O=C1C(Cc2ccccc2)C(=O)N(c2ccccc2)C(=O)N1Cc1ccccc1]
Compound 1-3

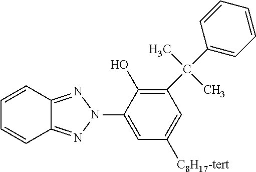

### <Preparation of Outer Layer Cellulose Acylate Dope 1>

10 parts by mass of the following matting agent dispersion liquid 1 was added to 90 parts by mass of the core layer cellulose acylate dope 1 to prepare an outer layer cellulose acylate dope 1.

Matting agent solution

| | |
|---|---|
| Silica particles having average particle size of | 2 parts by mass |
| 20 nm (AEROSIL R972, manufactured by | |
| Nippon Aerosil Co., Ltd.) | |
| Methylene chloride (the first solvent) | 76 parts by mass |
| Methanol (the second solvent) | 11 parts by mass |
| Core layer cellulose acylate dope 1 | 1 part by mass |

### <Manufacture of Protective Film 1>

Three layers of the core layer cellulose acylate dope 1 and the outer layer cellulose acylate dopes 1 on both sides thereof were simultaneously casted from a casting port onto a drum at 20° C. In a state where a content of the solvent in the film on the drum was approximately 20% by mass, the film was peeled from the drum, and both ends of the obtained film in the width direction were fixed with tenter clips, and in a state where a content of the residual solvent in the film was 3% to 15% by mass, the film was stretched 1.2 times in the transverse direction and dried. Thereafter, the obtained film was transported between the rolls of a heat treatment device to manufacture a cellulose acylate film 1 with a thickness of 25 μm, which was used as a protective film 1.

[Manufacture of Protective Film 1 with Hardcoat Layer]

As a coating liquid for forming a hardcoat layer, a curable composition (hardcoat 1) for a hardcoat shown in the following table was prepared.

TABLE 1

| | Monomer | | | | UV initiator | | |
|---|---|---|---|---|---|---|---|
| | | | | Total addition | | Addition | |
| | | | | amount | | amount | |
| | | | Monomer 1/ | [parts | | [parts | |
| | Monomer 1 | Monomer 2 | Monomer 2 | by mass] | Type | by mass] | Solvent |
| Hardcoat 1 | Pentaerythritol | Pentaerythritol | 3/2 | 53.5 | UV initiator 1 | 1.5 | Ethyl acetate |
| | triacrylate | tetraacrylate | | | | | |

The structure of a UV initiator 1 in Table 1 above is shown below.

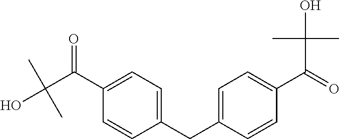 [SMILES: CC(C)(O)C(=O)c1ccc(Cc2ccc(C(=O)C(C)(C)O)cc2)cc1]

The curable composition for a hardcoat was applied onto a surface of the protective film 1 manufactured above, then dried at 100° C. for 60 seconds, irradiated with UV at 1.5 kW and 300 mJ under the conditions of 0.1% or less of nitrogen, and cured to manufacture a protective film 1 with a hardcoat layer, having a hardcoat layer with a film thickness of 5 μm. Furthermore, the film thickness of the hardcoat layer was adjusted by adjusting a coating amount by a die coating method, using a slot die.

[Manufacture of Polarizing Plate 1 with Protective Film on One Surface]

### (1) Saponification of Film

The manufactured protective film 1 with a hardcoat layer was immersed for 1 minute in a 4.5 mol/L aqueous sodium hydroxide solution (saponified solution) whose temperature had been adjusted to 37° C., and then the film was washed with water, then immersed in a 0.05 mol/L aqueous sulfuric acid solution for 30 seconds, and then further passed through a water washing bath. Then, the obtained film was repeatedly dehydrated three times with an air knife to drop water, and then the film was dried by leaving it in a drying zone at 70° C. for 15 seconds to manufacture a protective film 1 with a hardcoat layer, which had been saponified.

### (2) Manufacture of Polarizer

According to Examples of JP2016-148724A, a polarizer with a film thickness of 15 μm was prepared by providing a peripheral speed difference between two pairs of nip rolls and performing stretching in the longitudinal direction. The polarizer thus manufactured was used as a polarizer 1.

### (3) Bonding

The polarizer 1 thus obtained and the protective film 1 with a hardcoat layer which had subjected to the saponification treatment were bonded in a roll-to-roll manner so that the polarizing axis and the longitudinal direction of the film are orthogonal to each other, using a 3% aqueous PVA (manufactured by Kuraray Co., Ltd., PVA-117H) solution as an adhesive, thereby manufacturing a polarizing plate 1 with a protective film on one surface thereof (hereinafter also simply referred to as a “polarizing plate 1”). At this time, bonding was performed so that the cellulose acylate film side of the protective film was on the polarizer side.

### [Manufacture of First Polarizing Plate]

The optically anisotropic layer of the manufactured optical laminate and the polarizer surface of the polarizing plate 1 were attached to each other, using a 3% aqueous PVA (PVA-117H, manufactured by Kuraray Co., Ltd.) solution as an adhesive such that the polarization axis was orthogonal to the longitudinal direction of the film according to roll-to-roll processing, thereby manufacturing a first polarizing plate.

### [Manufacture of Protective Film 2]

### <Manufacture of Polymethyl Methacrylate (PMMA) Dope>

The following dope composition was put into a mixing tank and stirred to dissolve each component to prepare a PMMA dope.

PMMA Dope

| | |
|---|---|
| PMMA resin | 100 parts by mass |
| Sumilizer GS (manufactured by | 0.1 parts by mass |
| Sumitomo Chemical Co., Ltd.) | |
| Dichloromethane | 426 parts by mass |
| Methanol | 64 parts by mass |

### <Manufacture of Protective Film 2>

The above-mentioned PMMA dope was uniformly cast on a stainless steel-made band (casting support) from a casting die (band casting machine). The film was peeled in a state where the solvent content in the cast film was approximately 20% by mass, and the both ends of the film in the width direction were fixed with tenter clips and dried while the film was stretched at a stretching ratio of 1.1 times in the transverse direction. Thereafter, the obtained film was transported between the rolls of a heat treatment device and further dried to manufacture a PMMA film with a film thickness of 20 μm, which was used as a protective film 2.

### [Manufacture of Second Polarizing Plate]

### <Preparation of Adhesive Composition 1>

The following compounds were mixed at a ratio described to manufacture an adhesive composition 1.

Polymerizable compound (ARONIX M-220, manufactured by Toagosei Co., Ltd.): 20 parts by mass

4-Hydroxybutyl acrylate (manufactured by Nihon Kasei Co., Ltd.): 40 parts by mass

Polymerizable compound (2-Ethylhexyl acrylate, manufactured by Mitsubishi Chemical Corporation): 40 parts by mass

Polymerizable initiator (Irgacure 907, manufactured by BASF): 1.5 parts by mass

Sensitizer (KAYACURE DETX-S, manufactured by Nippon Kayaku Co., Ltd.): 0.5 parts by mass

### <Manufacture of Second Polarizing Plate>

The polarizer-bonded surface of the protective film 2 was subjected to a corona treatment with a discharge amount of 150 W·min/m², and then the adhesive composition 1 was coated so as to have a film thickness of 0.5 μm.

Then, the adhesive-coated surface was bonded to the polarizer surface of the polarizing plate 1 with a protective film on one surface, and irradiated with ultraviolet rays from the substrate side of the protective film 2 at 300 mJ/cm² at 40° C. in an air atmosphere. Thereafter, the resultant was dried at 60° C. for 3 minutes to manufacture a second polarizing plate.

### [Manufacture of Liquid Crystal Display Device]

Polarizing plates on the front and back surfaces from a commercially available liquid crystal display device (iPad (registered trademark), manufactured by Apple Inc.) (liquid crystal display device including a liquid crystal cell in an FFS mode) were peeled, and thus, the first polarizing plate including the optical laminate manufactured above was bonded on the viewing side and the second polarizing plate was bonded on a backlight side with a 20 μm acrylic pressure sensitive adhesive so that the alignment direction of the liquid crystal in the liquid crystal cell was orthogonal to the absorption axis of the polarizer in the first polarizing plate, thereby manufacturing a liquid crystal display device of Example 1.

Furthermore, the liquid crystal cell in the liquid crystal display device includes a color filter layer on the substrate on the first polarizing plate side and the TFT layer on the substrate on the second polarizing plate side, and the Rth (550) of both the layers were 10 nm and 2 nm, respectively. In addition, And of the liquid crystal compound in the liquid crystal cell was 340, and the tilt angle of the liquid crystal compound with respect to the substrate surface was 0.1°.

### <Evaluation of Display Performance>

A black brightness and a chromaticity were measured using a measuring device (EZ-Contrast XL88, manufactured by ELDIM) during the black display of a liquid crystal display device in a dark room.

Specifically, for the black brightness, an average value of the brightness at azimuth angles of 45°, 135°, 225°, and 315° at a polar angle of 60° was measured as a light leak Y, and for the chromaticity, chromaticities u′ and v′ were calculated with an increment of 15° at an azimuthal angle from 0° to 345° at a polar angle of 60°, and evaluated in accordance with the following standard.

### (Evaluation Standard)

A: No change was confirmed, as compared with a liquid crystal display device formed of an optical laminate in which a barrier layer was not formed (hereinafter simply referred to as a “comparative device” in this paragraph).
B: There was a change, as compared with the comparative device, but the change could not be confirmed by visual evaluation.
C: A change could be visually confirmed, as compared with the comparative device.

TABLE 2

| | Composition for forming barrier layer | | | | | | | |
|---|---|---|---|---|---|---|---|---|
| | | | | | | | | Polymerizable |
| | | | | | | | | group equivalent |
| | | | | | | | | (molecular weight |
| | Monomer 1 | | Monomer 2 | | Monomer 3 | | Leveling | of monomer/number |
| | | Ratio | | Ratio | | Ratio | agent | of polymerizable |
| | Name | (%) | Name | (%) | Name | (%) | Name | groups) |
| Example 1 | A-TMMT | 71.8 | A-6(00 | 23.9 | B-1 | 4.3 | Leveling | 132 |
| | | | | | | | agent P3 | |
| Example 2 | A-TMMT | 71.8 | A-600 | 23.9 | B-1 | 4.3 | Leveling | 132 |
| | | | | | | | agent P3 | |
| Example 3 | A-TMMT | 95.7 | | | B-1 | 4.3 | Leveling | 91 |
| | | | | | | | agent P3 | |
| Example 4 | A-TMMT | 95.7 | | | B-1 | 4.3 | Leveling | 91 |
| | | | | | | | agent P3 | |
| Example 5 | A-TMMT | 95.7 | | | B-1 | 4.3 | Leveling | 91 |
| | | | | | | | agent P3 | |
| Example 6 | A-TMMT | 71.8 | A-600 | 23.9 | B-1 | 4.3 | Ion | 132 |
| | | | | | | | compound A | |
| | | | | | | | (2 parts | |
| | | | | | | | by mass) | |
| | | | | | | | KBE-9301P | |
| | | | | | | | (0.5 parts | |
| | | | | | | | by mass) | |
| Example 7 | A-TMMT | 71.8 | A-600 | 23.9 | B-1 | 4.3 | Leveling | 132 |
| | | | | | | | agent P4 | |
| Example 8 | A-TMMT | 71.8 | A-600 | 23.9 | B-1 | 4.3 | Leveling | 132 |
| | | | | | | | agent P5 | |
| Example 9 | Liquid | 89.0 | A-TMMT | 6.7 | B-1 | 4.3 | Leveling | 290 |
| | crystal | | | | | | agent P3 | |
| | compound | | | | | | | |
| | L1 | | | | | | | |
| Example 10 | A-TMMT | 95.7 | | | B-1 | 4.3 | Leveling | 91 |
| | | | | | | | agent P3 | |
| Comparative | A-TMMT | 71.8 | A-600 | 23.9 | B-1 | 4.3 | — | 132 |
| Example 1 | | | | | | | | |
| Comparative | PET-30 | 95.7 | | | B-1 | 4.3 | Leveling | 95 |
| Example 2 | | | | | | | agent P3 | |
| Comparative | A-TMMT | 47.85 | BLEMMER | 47.85 | B-1 | 4.3 | Leveling | 151 |
| Example 3 | | | GLM | | | | agent P3 | |

| | Barrier layer | | | | | |
|---|---|---|---|---|---|---|
| | | | | Monomer shrinkage | | |
| | | | | amount S | | |
| | | | | (thickness/ | Performance evaluation | |
| | Thickness | Condition | Condition | polymerizable | | Display |
| | (μm) | 1 | 2 | group equivalent) | Adhesiveness | performance |
| Example 1 | 0.8 | A | A | 0.0061 | A | A |
| Example 2 | 2 | A | A | 0.0152 | A | A |
| Example 3 | 0.8 | A | A | 0.0088 | A | A |
| Example 4 | 2 | A | A | 0.0220 | A | B |
| Example 5 | 4 | A | A | 0.0440 | A | B |
| Example 6 | 0.8 | A | A | 0.0074 | A | A |
| Example 7 | 2 | A | A | 0.0152 | A | A |
| Example 8 | 2 | A | A | 0.0152 | A | A |
| Example 9 | 0.8 | A | A | 0.0028 | A | B |
| Example 10 | 10 | A | A | 0.1099 | A | C |
| Comparative | 0.8 | B | A | 0.0061 | C | A |
| Example 1 | | | | | | |
| Comparative | 0.8 | A | B | 0.0084 | B | A |
| Example 2 | | | | | | |
| Comparative | 0.8 | A | B | 0.0053 | C | A |
| Example 3 | | | | | | |

The structures of the compounds used as the monomer 1, the monomer 2, and the leveling agent in Table 2 are shown below.

A-TMMT (manufactured by Shin-Nakamura Chemical Co., Ltd.)

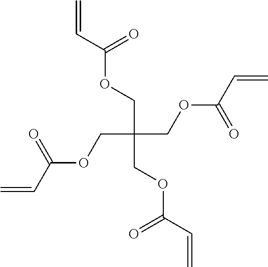 [SMILES: C=CC(=O)OCC(COC(=O)C=C)(COC(=O)C=C)COC(=O)C=C]

Liquid crystal compound L1

Mixture of the following liquid crystal compounds (RA), (RB), and (RC) at a ratio of 83:15:2 (mass ratio)

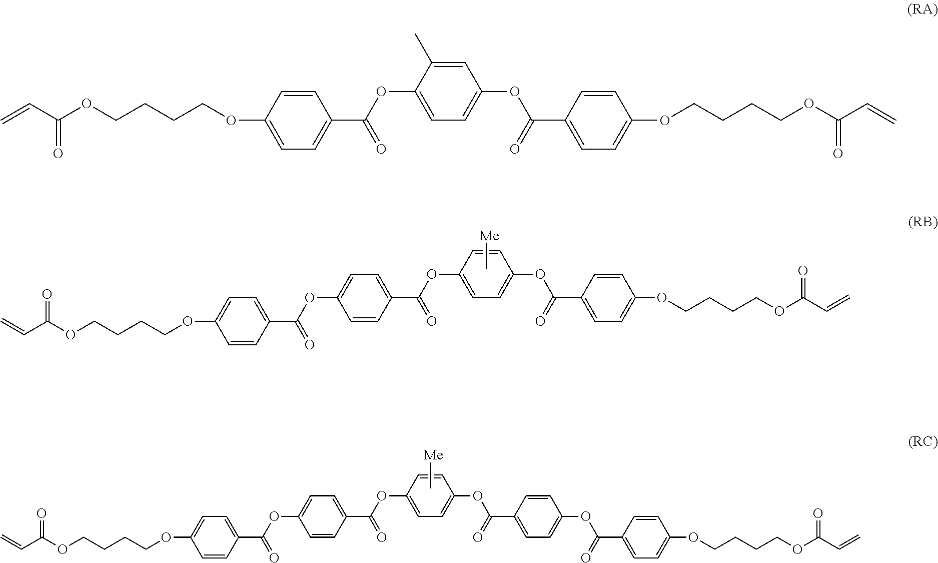

PET-30 (mixture of a compound represented by the following formula with a≈3 and b≈1 and a compound represented by the formula with a=4 and b=0, manufactured by Nippon Kayaku Co., Ltd.)

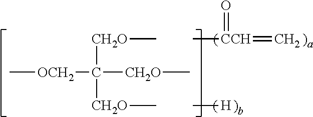

A-600 (manufactured by Shin-Nakamura Chemical Co., Ltd.)

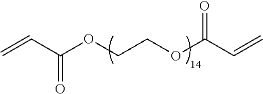

BLEMMER GLM (manufactured by NOF Corporation)

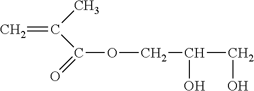

Leveling agent P3<weight-average molecular weight: 11,000, the numerical values in the following formulae indicate contents (% by mole) of the respective repeating units with respect to all the repeating units>

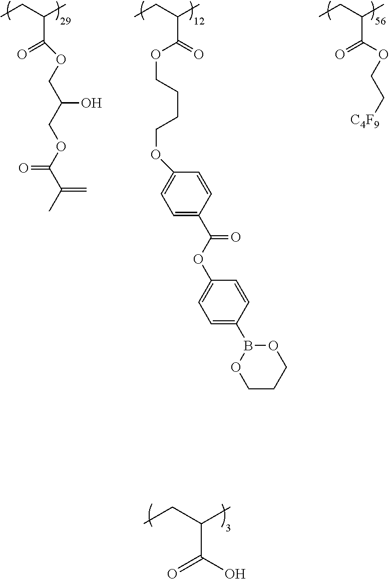

Ion compound A

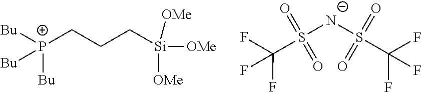

KBE-9301P

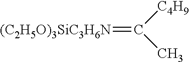

Leveling agent P4<the numerical values in the following formulae indicate contents (% by mole) of the respective repeating units with respect to all the repeating units>

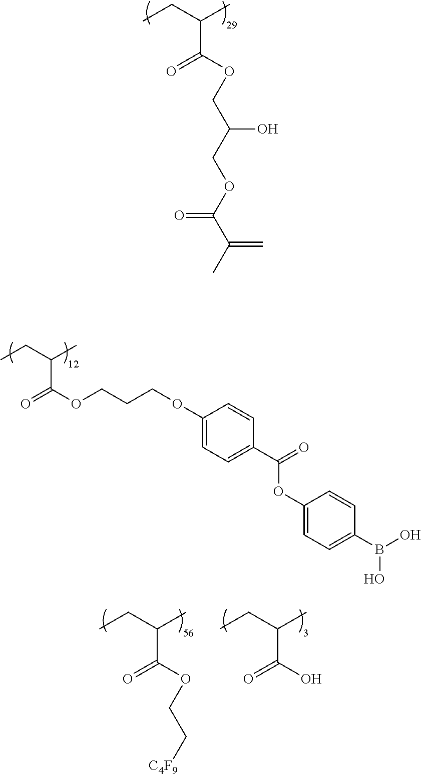

Leveling agent P5<the numerical values in the following formulae indicate contents by mole) of the respective repeating units with respect to all the repeating units>

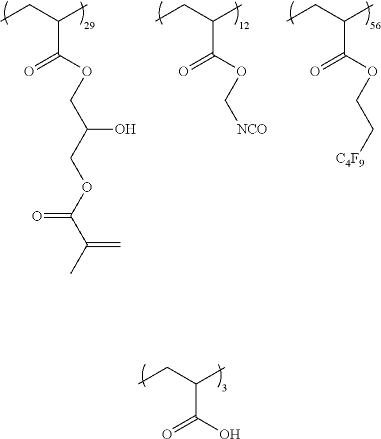

From the results shown in Table 2, it was found that the optical laminate having a barrier layer not satisfying any one of the condition 1 or Condition 2 had poor adhesiveness to the pressure sensitive adhesive layer (Comparative Examples 1 to 3).

On the contrary, it was found that the optical laminate having a barrier layer satisfying both of Condition 1 and Condition 2 had excellent adhesiveness to the pressure sensitive adhesive layer (Examples 1 to 10).

In particular, from the comparison of Examples 1 to 4, it was found that in a case where the monomer shrinkage amount S was 0.02 or less, the display performance was improved.

Moreover, from the comparison between Example 1 and Example 9, it was found that in a case where the composition for forming a barrier layer did not contain the liquid crystal compound, the display performance was improved.

In addition, from the comparison between Example 1 and Example 10, it was found that in a case where the monomer shrinkage amount S was 0.1 or less, the display performance was improved.

What is claimed is:

1. An optical laminate comprising, in the following order:
a film substrate;
a barrier layer; and
a pressure sensitive adhesive layer,
wherein the barrier layer is formed of a composition for forming a barrier layer, containing a monomer having a polymerizable group, and satisfies Conditions 1 and 2,
Condition 1: a functional group that reacts with a hydroxyl group to form a covalent bond is present on a surface of the barrier layer on a pressure sensitive adhesive layer side, and
Condition 2: no hydroxyl group other than the hydroxyl group included in the functional group is present in a region from the surface of the barrier layer on the pressure sensitive adhesive layer side to a half of a thickness of the barrier layer.

2. The optical laminate according to claim 1,
wherein a polarizer is not provided between the film substrate and the barrier layer.

3. The optical laminate according to claim 1,
wherein the barrier layer does not exhibit liquid crystallinity.

4. The optical laminate according to claim 1,
wherein a monomer shrinkage amount S represented by the following expression is 0.1 or less,
Monomer shrinkage amount S=Thickness (μm) of barrier layer/Polymerizable group equivalent of monomer,
where the polymerizable group equivalent is calculated as [Molecular weight of monomer]/[Number of polymerizable groups per molecule of monomer].

5. The optical laminate according to claim 4,
wherein the monomer shrinkage amount S is 0.02 or less.

6. The optical laminate according to claim 1,
wherein the film substrate consists of a cycloolefin-based polymer film.

7. The optical laminate according to claim 1, further comprising:
an optically anisotropic layer,
wherein the optical laminate includes the optically anisotropic layer, the film substrate, the barrier layer, and the pressure sensitive adhesive layer in this order.

8. A polarizing plate comprising:
a polarizer; and
the optical laminate according to claim 1.

9. A polarizing plate comprising:
a polarizer; and
the optical laminate according to claim 2.

10. A polarizing plate comprising:
a polarizer; and
the optical laminate according to claim 3.

11. A polarizing plate comprising:
a polarizer; and
the optical laminate according to claim 4.

12. A polarizing plate comprising:
a polarizer; and
the optical laminate according to claim 5.

13. A polarizing plate comprising:
a polarizer; and
the optical laminate according to claim 6.

14. A polarizing plate comprising:
a polarizer; and
the optical laminate according to claim 7.

15. The polarizer plate according to claim 8,
wherein the polarizer, as well as the film substrate, the barrier layer, and the pressure sensitive adhesive layer that are included in the optical laminate are provided in an order of the polarizer, the film substrate, the barrier layer, and the pressure sensitive adhesive layer.

16. The polarizer plate according to claim 9,
wherein the polarizer, as well as the film substrate, the barrier layer, and the pressure sensitive adhesive layer that are included in the optical laminate are provided in an order of the polarizer, the film substrate, the barrier layer, and the pressure sensitive adhesive layer.

17. An image display device comprising:
the optical laminate according to claim 1.

18. An image display device comprising:
the optical laminate according to claim 2.

19. The image display device according to claim 17,
wherein the image display device is a liquid crystal display device.

20. The image display device according to claim 17,
wherein the image display device is an organic electroluminescent display device.
